(19) United States
(12) Patent Application Publication
(10) Pub. No.: US 2004/0166606 A1
(43) Pub. Date: Aug. 26, 2004

(54) Low temperature wafer-level micro-encapsulation

(76) Inventor: David Forehand, Plano, TX (US)

Correspondence Address: CARR LAW FIRM, L.L.P., 670 FOUNDERS SQUARE, 900 JACKSON STREET, DALLAS, TX, 75202, US

(21) Appl. No.: 10/726,399

(22) Filed: Dec. 3, 2003

Related U.S. Application Data
(60) Provisional application No. 60/450,637, filed on Feb. 26, 2003.

(51) Int. Cl. H01L 21/50

(52) U.S. Cl. 438/106

(57) ABSTRACT

A method and apparatus are provided for encapsulated micro-devices. More particularly, Microelectromechanical Systems (MEMS) switches are encapsulated. The method and apparatus involve the creation of a cage structure over the micro-devices and the application of a low-temperature liquid protective material onto the cage and subsequent curing to form a hermetic micro-encapsulation. The technique and devices employ the use of conventional semiconductor manufacturing equipment that greatly increase productivity and reduces costs over more conventional techniques and devices for protect similar micro-devices.

### CLAIM OF PRIORITY

This application claims priority from U.S. Provisional Patent Application No. 60/450,637 entitled “MEMBRANE SWITCH COMPONENTS AND DESIGNS” by David Forehand, filed on Feb. 24, 2003 (Attorney Docket No. 2657000) and is hereby incorporated by reference.

### BACKGROUND OF THE INVENTION

1. Field of the Invention

The present invention relates generally to the packaging of electromechanical or micromachined devices and, more particularly, to individual encapsulation of microelectromechanical system (MEMS) and micromachined devices, such as sensors, actuators, and/or switches.

2. Description of the Related Art

MEMS and micromachined devices are presently utilized for a variety of sensor, imaging, and actuation applications. These include acceleration and pressure sensors for automotive and biomedical applications, infrared sensor arrays and arrays of micromirrors for imaging and displays, and RF switches for controlling and routing wireless signals. The unique characteristics of these devices, including their superior ruggedness, reduced size, and low potential cost, can allow them to become an enabling technology for a variety of military and commercial applications. However, the present challenge in the development of this technology is the effective, low-cost packaging of these devices. The requirement for a hermetic package that makes no contact with the MEMS circuitry creates many packaging difficulties. In addition, the need for a controlled atmosphere or vacuum within the package is an extra constraint not normally encountered in packaging of more conventional electronic devices. As such, several methods have been investigated to resolve these packaging problems.

Currently, there are two general approaches that can be employed to protect MEMS circuitry. The first method involves encasing the MEMS circuitry in traditional, hermetic ceramic or metal packages with a lid. However, this approach has several disadvantages, such as being bulky, expensive, and requiring much back-end processing and assembly (which leads to a yield loss). For example, in Radio Frequency (RF) applications, a ceramic package may not be desirable due to its high RF losses, which significantly reduce the low-loss advantages of RF MEMS, and due to its difficulties in tuning the RF ceramic package to the desired frequency, which worsens as the frequency increases.

A second method, wafer-level packaging, has recently been utilized to incorporate the advantages of batch processing to the packaging process. This enables the packaging to be accomplished at the wafer-level, within the environs of a cleanroom. This substantially reduces cost and improves the yield of packaged MEMS circuitry. Fundamentally, these process forms of packaging require a separate lid wafer to be processed. The processed lid wafer has a number of etched cavities that will be utilized to cover the MEMS. The etched lid wafer is then adhered to a wafer containing a multitude of MEMS devices. However, a large seal ring around each MEMS circuit is required to implement the bonding of the two wafers. Moreover, to make electrical connections with the MEMS circuitry requires a through-wafer via channel or RF feed-through underneath the seal ring. Depending on circuit requirements, this connection may be both difficult and/or expensive to manufacture. Wafer-level packaging therefore has its own set of disadvantages, more particularly, requiring significant seal ring area, precise double-wafer alignment and bonding, while incorporating difficulties in electrical interconnections, susceptibility to wafer surface roughness, and possibly utilizing high-temperature processing.

More recently, techniques have been established to fabricate and encapsulate a protective housing around the MEMS devices. However, these techniques utilize vacuum encapsulation, high temperature processing, and molten metal sealing for hermeticity. While there are classes of devices which operate in the near-vacuum conditions, can tolerate high processing temperatures (>600° C.), and are not impacted by the close proximity of metallized seal surfaces, these are a limited subset of overall MEMS devices.

Therefore, there is a need for a MEMS packaging technique that is both economical and easy to implement for a large variety of MEMS and micromachined devices to allow for widespread use and manufacture of MEMS and micromachined devices.

### SUMMARY OF THE INVENTION

The present invention provides for packaging at least one microscopic device. A housing with at least one aperture is formed over the at least one microscopic device. A protective material is deposited, wherein the protective material is at least configured to have a viscosity such that the protective material does not flow into movable regions of at least one microscopic device. The protective material is cured.

### BRIEF DESCRIPTION OF THE DRAWINGS

For a more complete understanding of the present invention and the advantages thereof, reference is now made to the following descriptions taken in conjunction with the accompanying drawings, in which:

FIG. 1 is a flow chart depicting the process for the creation of a micro-encapsulated package to protect the MEMS or micromachined device;

FIG. 2 is a block diagram depicting a sacrificial layer deposited on a MEMS device;

FIG. 3 is a block diagram depicting a structural layer deposited on a sacrificial layer and a MEMS device;

FIG. 4 is a block diagram depicting protective cage on a MEMS device with the sacrificial layer removed; and

FIG. 5 is a block diagram depicting protective layer deposited on the protective cage.

### DETAILED DESCRIPTION

In the following discussion, numerous specific details are set forth to provide a thorough understanding of the present invention. In particular, the details are specific to packaging for MEMS and micromachined devices, or other similarly electromechanical devices. Many of these applications require insulating materials to form the microcavity and package. However, those skilled in the art will appreciate that the present invention can be practiced, with other materials, without such specific details. In other instances, well-known elements have been illustrated in schematic or block diagram form in order not to obscure the present invention in unnecessary detail.

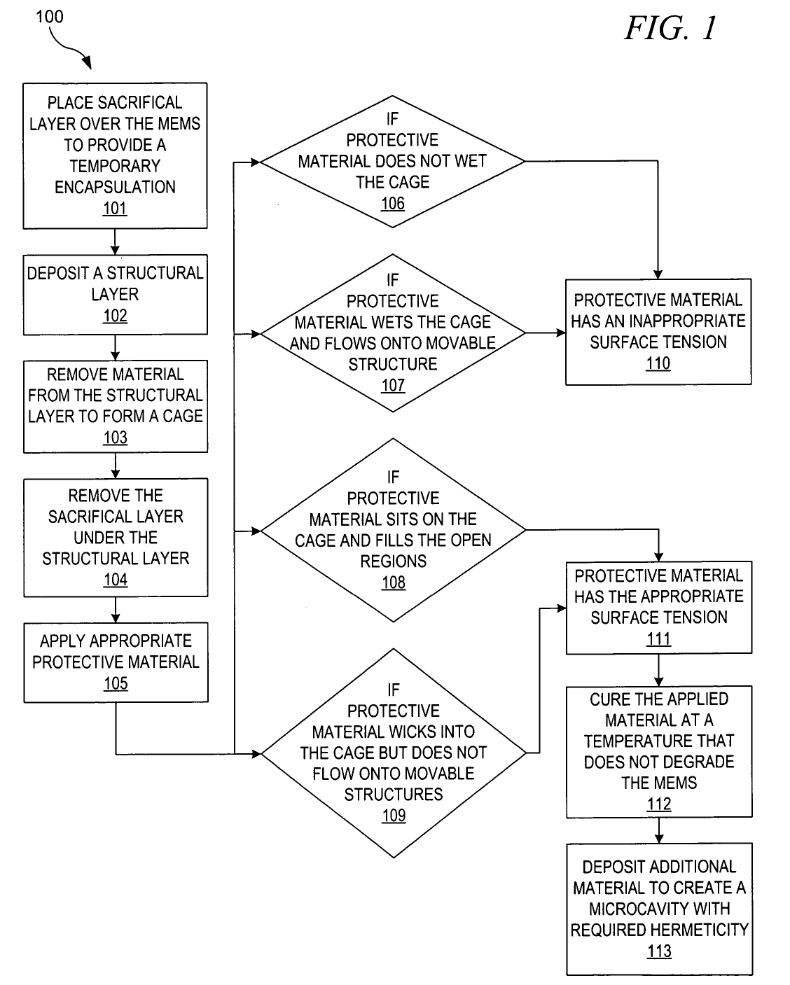

Referring to FIG. 1 of the drawings, the reference numeral 100 generally designates a flow chart depicting the process for the creation of a micro-encapsulated package to protect the MEMS or micromachined device.

During the process of encapsulating a MEMS or a micromachined device, certain underlying conditions for the process as a whole are typically preset. Conditions, such as the atmospheric composition of the processing environment, can have a substantial impact on process and can affect the resulting product. For the process of the creation of a micro-encapsulated package to protect the MEMS or micromachined device, typically an inert gas atmosphere with a pressure above 1 Pascal is utilized. Also, during the entire process the temperature of the atmosphere or the devices should typically not rise above 600° C. or above a temperature sufficient to melt or damage a MEMS or micromachined device.

Additionally, the process for the creation of a micro-encapsulated package to protect the MEMS or micromachined device 100 is more applicable to a wider variety of MEMS and micromachined devices compared to conventional techniques and processes. The process 100 utilizes conventional semiconductor and micromachining manufacturing devices to form and remove material layers. Also, the process 100 is amenable to both vacuum and controlled atmosphere packaging and utilizes significantly lower temperature than the melting point of aluminum. Also, the process 100 incorporates insulating materials for the hermetic encapsulation. This gives the process 100 a much wider range of applicability, for example certain RF MEMS.

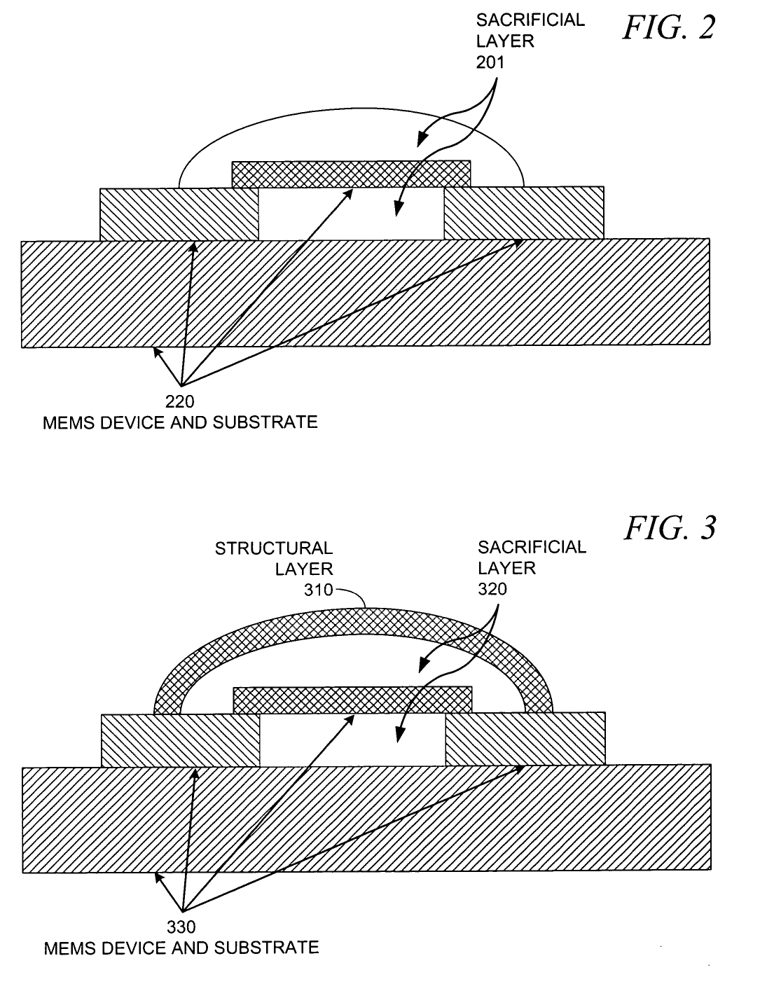

In step 101, a sacrificial layer is placed over the MEMS device or devices to form a temporary encapsulation. The sacrificial layer can be composed of a variety of materials. For example, an organic material such as a photoresist or polyimide can be used. However, the sacrificial layer should possess the property of easy removal by heat, wet chemical etching, or plasma etching. Moreover, the thickness of the sacrificial layer can also vary. The sacrificial layer should be thick enough such that during operation, the movable membrane does not contact the housing and be thick enough to prevent contact between the movable region and the subsequent liquid protective material application, typically between 0.2-10 microns thick. FIG. 2 illustrates a sacrificial layer 201 covering a MEMS device and substrate 220.

In step 102, a structural material is deposited on top of the sacrificial layer. For many applications, such as with RF MEMS, the structural layer should be an insulator. For example, Silicon Dioxide (SiO₂) or Silicon Nitride (Si₃N₄) can be used. However, a conductor can be used as a structural layer. The choice of the structural layer will depend on desired electrical properties of the packaging. A variety of materials, though, including metals, can be used. Moreover, the thickness of the non-sacrificial, structural layer can vary, but should have sufficient structural integrity so as to support the subsequent application of a liquid encapsulating material. The structural layer, though, may be between 0.2-20 microns thick and should have tensile to slightly compressive stress. Furthermore, there are a variety of manners to deposit the structural layer. However, the method employed should operate at a low temperature that will not adversely impact the MEMS or the sacrificial layer or sacrificial layers. Also, FIG. 3 depicts a structural layer 310 deposited on top of a sacrificial layer 320 and a MEMS device and substrate 330.

In step 103, open regions within the cage structure are formed by removing material from the structural layer. There are a variety of means to remove portions of the structural layer that can include, but not limited to, sputtering, plasma etching, and wet etching. The size of the apertures of the cage can also vary. However, the size and spacing of the apertures should be large enough and/or spaced close enough such that the sacrificial layer can be later removed, but the apertures should be small enough as to not allow the protective material, such as Spin-On Glass (SOG), to encroach into the cavity and contact the movable structure. In addition, there should remain sufficient material to be structurally strong enough to not collapse upon application of the protective, encapsulating material.

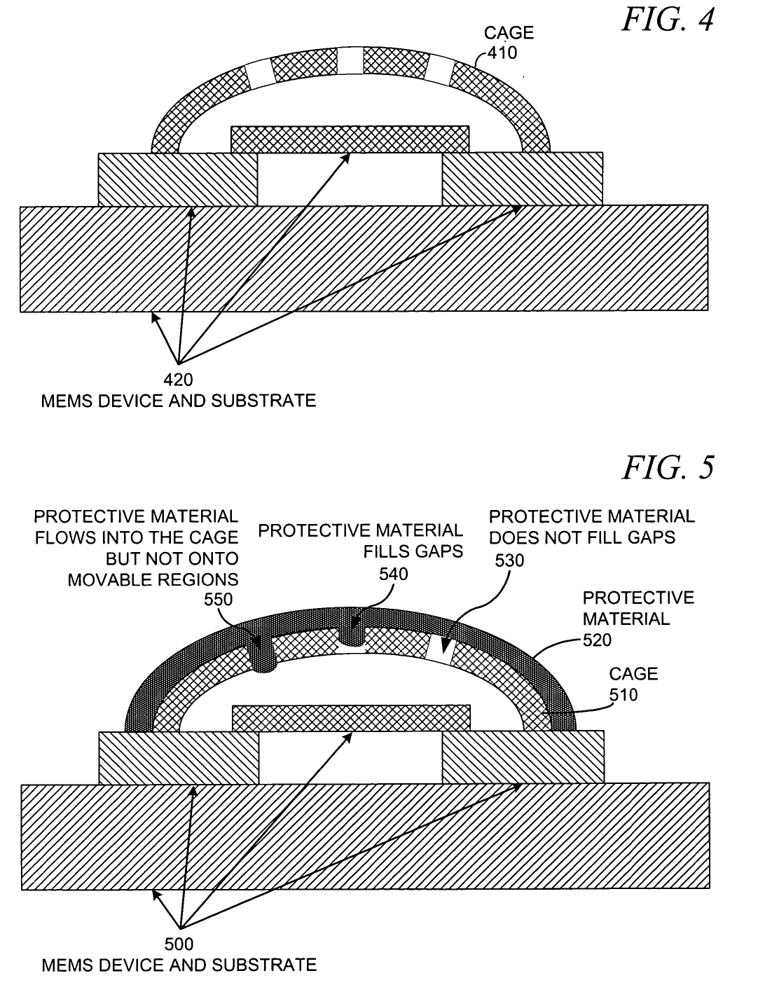

In step 104, the sacrificial layer is removed to create a microcavity in the space between the cage and the MEMS or micromachined device. There are a variety of manners to remove the sacrificial layer. For example, sublimation, sputter etching, ion beam milling, plasma ashing or use of wet chemicals can be employed. Also, FIG. 4 depicts a cage 410 deposited on top of a MEMS device 420.

In step 105, the appropriate protective material is applied to encapsulate the MEMS device. The appropriate material is selected by virtue of the properties of the material, more particularly, viscosity, surface tension, and hermeticity after curing or fixing. FIG. 5 depicts protective material 520 deposited on a cage 510 on top of a MEMS device and substrate 500.

There are certain liquids that possess inappropriate properties. According to steps 106 and 110, if the protective material does not wet the cage, then the surface tension is too high, and the material is not appropriate. According to steps 107 and 110, if the protective material wicks into the microcavity and contacts any movable portions of the device to be protected, for example a MEMS device, then the surface tension is too low, and the material is not appropriate.

However, there can be liquids that possess appropriate properties to protect the MEMS or micromachined devices. According to steps 108 and 111, if the protective material sits on top of the cage, which may also fill or partially fill the gaps and open regions of the cage, 530 and 540 of FIG. 5, then the material is appropriate because the surface tension is within the desired range. According to steps 109 and 111, if the protective material wicks into the cage but does not wick onto the movable regions of the device to be protected 550 of FIG. 5, for example a MEMS device, then the material is appropriate because to the surface tension is within the desired range.

According to step 112, after the appropriate material has been applied, the appropriate material is cured or fixed to seal the device to be packaged. The cured or fixed material should provide a hermetic barrier to prevent the ingress or egress of gasses or particles into the protective cavity. A unique feature of this technique is that the final sealing process can be configured to incorporate either an inert atmosphere or a vacuum atmosphere within the package microcavity. Depending on the type of device, one of these two environments may be more desirable. For example, infrared bolometers and micromechanical resonators typically require a vacuum atmosphere to operate properly. Conversely, optical micromirror arrays and RF MEMS switches only require a dry, inert gas environment. There are a variety of materials that can be used as a protective material that include, but not limited to, spin-on-glass (SOG). Another unique feature of this process is that the application of the protective material and encapsulation of the microcavity can be accomplished at relatively low temperatures, for example below 600° C. The temperature should be necessary to cure or fix the protective material. The protective material should also possess the properties of structural strength, non-conductivity of electricity, hermeticity, and low processing temperatures. However, depending on the desired use, the structural integrity of the material, its process temperatures, and its ability to conduct electricity can vary.

In step 113, additional material may be deposited onto the wafer. Typically, the additional material is to increase the hermeticity of the packaged microcavity. However, step 113 may be necessary depending on the desired application. The additional material can be the same or similar material to structural layer and depends on desired electrical properties. For example, for an RF MEMS application, the additional material can be Silicon Dioxide (SiO₂) or Silicon Nitride (Si₃N₄).

It will further be understood from the foregoing description that various modifications and changes can be made in the preferred embodiment of the present invention without departing from its true spirit. This description is intended for purposes of illustration only and should not be construed in a limiting sense. The scope of this invention should be limited only by the language of the following claims.

1. A method for packaging at least one microscopic device, comprising:
applying a sacrificial material to at least one microscopic device;
applying a layer of structural material adjacent the sacrificial material, the layer of structural material forming a housing adjacent at least a portion of the sacrificial material;
creating one or more apertures in the housing of structural material to expose at least a portion of the adjacent sacrificial material;
removing the sacrificial layer, wherein the housing of structural material with at least one aperture remains;
depositing a protective material adjacent the housing of structural material overlaying at least one aperture of the housing; and
curing the protective material.

2. The method of claim 1, wherein the method further comprises:
providing a gas atmosphere, wherein the pressure is greater than or equal to 1 Pascal (Pa); and
providing a temperature of less than 600° Celsius (C).

3. The method of claim 2, wherein the sacrificial material has a higher etch rate than the structural material.

4. The method of claim 3, wherein the sacrificial material comprises either a photoresist or a polyimide material.

5. The method of claim 2, wherein the structural layer is selected from a group of Silicon Dioxide (SiO₂) and Silicon Nitride (Si₃N₄).

6. The method of claim 2, wherein the step of removing portions of the structural layer comprises use of sputter etching or ion beam milling.

7. The method of claim 2, wherein the step of removing the sacrificial layer comprises use chemical etching.

8. The method of claim 2, wherein the step of removing the sacrificial layer comprises use of either plasma ashing or plasma etching.

9. The method in claim 2, wherein the step of depositing a protective material comprises wicking the protective material into at least one aperture of the housing.

10. The method of claim 2, wherein the step of depositing the protective material comprises applying the protective material to at least a portion of the surface of the housing and allowing the protective material to flow into at least a portion of an aperture in the housing.

11. The method of claim 2, wherein the step of applying a layer of material comprises forming a structural layer having a thickness of between about 0.2 microns and about 20 microns.

12. The method of claim 2, wherein the step of applying a sacrificial material comprises forming a sacrificial layer having a thickness of between about 0.2 microns and about 10 microns.

13. An apparatus for packaging at least one microscopic device, comprising:
means for applying a sacrificial material to at least one microscopic device;
means for applying a layer of structural material adjacent the sacrificial material, the layer of structural material forming a housing adjacent at least a portion of the sacrificial material;
means for creating one or more apertures in the housing of structural material to expose at least a portion of the adjacent sacrificial material;
means for removing the sacrificial layer, wherein the housing of structural material with at least one aperture remains;
means for depositing a protective material adjacent the housing of structural material overlaying at least one aperture of the housing; and
means for curing the protective material.

14. The apparatus of claim 13, the apparatus further comprises a means for providing a gas atmosphere, wherein the pressure is greater than or equal to 1 Pascal (Pa).

15. The apparatus of claim 14, wherein the apparatus further comprises a means for providing a temperature of less than 600° Celsius (C).

16. The apparatus of claim 13, wherein means for applying a structural material is configured to utilize a structural layer is selected from a group of Silicon Dioxide (SiO₂) and Silicon Nitride (Si₃N₄).

17. The apparatus of claim 13, wherein means for removing portions of the structural layer is at least configured to use sputter etching or ion beam milling.

18. The apparatus of claim 13, wherein the means for removing the sacrificial layer is at least configured to use chemical etching.

19. The apparatus of claim 13, wherein the means for removing the sacrificial layer is at least configured to use plasma ashing or plasma etching.

20. The apparatus in claim 13, wherein means for depositing a protective material is at least configured to utilize a protective material with a viscosity such that the protective material wicks into the housing with at least one aperture and is at least configured to not flow into movable structures.

21. The apparatus of claim 13, wherein means for depositing a protective material is at least configured to utilize a protective material with a viscosity such that the protective material fills the apertures of the housing with at least one aperture and remains on the surface of the housing with at least one aperture.

22. The apparatus of claim 13, wherein the means for applying a structural material applies a structural layer that is between 0.2 microns and 20 microns thick.

23. The apparatus of claim 13, wherein the means for applying a sacrificial layer applies a sacrificial that is between 0.2 microns and 10 microns thick.

24. A method for packaging at least one microscopic device, comprising:
forming a housing with at least one aperture over the microscopic device;
depositing a protective material adjacent at least a portion of the housing, wherein the protective material at least flows into at least one aperture of the housing, sealing the aperture, but does not flow into at least one of the movable regions of the microscopic device; and
curing the protective material.

25. The method of claim 24 wherein the step of forming of the housing with at least one aperture further comprises:
applying a sacrificial material to at least one microscopic device;
applying a layer of structural material adjacent the sacrificial material, the layer of structural material forming a housing adjacent at least a portion of the sacrificial material;
creating one or more apertures in the housing of structural material to expose at least a portion of the adjacent sacrificial material; and
removing the sacrificial layer, wherein the housing of structural material with at least one aperture remains.

26. The method of claim 25, wherein the sacrificial layer has a higher etch rate than the structural material.

27. The method of claim 26, wherein the sacrificial material comprises either a photoresist or a polyimide material.

28. The method of claim 25, wherein the structural layer is selected from a group of Silicon Dioxide (SiO₂) and Silicon Nitride (Si₃N₄).

29. The method of claim 25, wherein the step of removing portions of the structural layer is at least configured to use sputter etching or ion beam milling.

30. The method of claim 25, wherein the step of removing the sacrificial layer is at least configured to use chemical etching.

31. The method of claim 25, wherein the step of removing the sacrificial layer is at least configured to use plasma ashing or plasma etching.

32. The method of claim 25, wherein the step of applying a structural material comprises forming a structural layer between 0.2 microns and 20 microns thick.

33. The method of claim 25, wherein the step of applying a sacrificial material comprises forming a sacrificial layer is between 0.2 microns and 10 microns thick.

34. An apparatus for packaging a microscopic device, comprising:
mean for forming a housing with at least one aperture over the microscopic device;
means for depositing a protective material adjacent at least a portion of the housing, wherein the protective material at least flows into at least one aperture of the housing, sealing the aperture, but does not flow into at least one of the movable regions of the microscopic device; and
means for curing the protective material.

35. The apparatus of claim 34, wherein the means for forming a housing with at least one aperture further comprises:
means for applying a sacrificial material to at least one microscopic device;
means for applying a layer of structural material adjacent the sacrificial material, the layer of structural material forming a housing adjacent at least a portion of the sacrificial material;
means for creating one or more apertures in the housing of structural material to expose at least a portion of the adjacent sacrificial material; and
means for removing the sacrificial layer, wherein the housing of structural material with at least one aperture remains.

36. The apparatus of claim 35, wherein the means for applying a sacrificial material is at least configured to utilize sacrificial layer has a higher etch rate than the structural material.

37. The apparatus of claim 36, wherein the means for applying a sacrificial material is at least configured to utilize an organic material comprising with photoresist or polyimide.

38. The apparatus of claim 35, wherein the means for applying a structural material is at least configured to utilize a material selected from a group of Silicon Dioxide (SiO₂) and Silicon Nitride (Si₃N₄).

39. The apparatus of claim 35, wherein means for removing portions of the structural layer is at least configured to use sputter etching or ion beam milling.

40. The apparatus of claim 35, wherein the means for removing the sacrificial layer is at least configured to use chemical etching.

41. The apparatus of claim 35, wherein the means for removing the sacrificial layer is at least configured to use plasma ashing or plasma etching.

42. The apparatus of claim 35, wherein the means for applying a structural material applies a structural layer between 0.2 microns and 20 microns thick.

43. The apparatus of claim 35, wherein the means for applying a sacrificial material applies a sacrificial layer is between 0.2 microns and 10 microns thick.

44. A method for packaging at least one microscopic device, comprising:
forming a housing with at least one aperture over the at least one microscopic device;
depositing a protective material adjacent at least a portion of the housing, wherein the protective material flows at least partially into at least one aperture of the housing, sealing the aperture, but does not flow into at least one of the movable regions of the microscopic device; and
curing the protective material.

45. The method of claim 44 wherein the forming of the housing with at least one aperture further comprises:
applying a sacrificial material to at least one microscopic device;
applying a layer of structural material adjacent the sacrificial material, the layer of structural material forming a housing adjacent at least a portion of the sacrificial material;
creating one or more apertures in the housing of structural material to expose at least a portion of the adjacent sacrificial material; and
removing the sacrificial layer, wherein the housing of structural material with at least one aperture remains.

46. The method of claim 45, wherein the sacrificial layer has a higher etch rate than the structural material.

47. The method of claim 46, wherein the sacrificial material comprises either a photoresist or a polyimide material.

48. The method of claim 45, wherein the structural layer is selected from a group of Silicon Dioxide (SiO₂) and Silicon Nitride (Si₃N₄).

49. The method of claim 45, the step of removing portions of the structural layer is at least configured to use sputter etching or ion beam milling.

50. The method of claim 45, wherein the step of removing the sacrificial layer is at least configured to use chemical etching.

51. The method of claim 45, wherein the step of removing the sacrificial layer is at least configured to use plasma ashing or plasma etching.

52. The method of claim 45, wherein the step of applying a structural material comprises forming a structural layer between 0.2 microns and 20 microns thick.

53. The method of claim 45, wherein the step of applying a sacrificial material comprises forming a sacrificial layer is between 0.2 microns and 10 microns thick.

54. An apparatus for packaging at least one microscopic device, comprising:
means for forming a housing with at least one aperture over the at least one microscopic device;
means for depositing a protective material adjacent to at least a portion of the housing, wherein the protective material flows at least partially into at least one aperture of the housing, sealing the aperture, but does not flow into at least one of the movable regions of the microscopic device; and
means for curing the protective material.

55. The apparatus of claim 54 wherein the means for forming the housing with at least one aperture further comprises:
means for applying a sacrificial material to at least one microscopic device;
means for applying a layer of structural material adjacent the sacrificial material, the layer of structural material forming a housing adjacent at least a portion of the sacrificial material;
means for creating one or more apertures in the housing of structural material to expose at least a portion of the adjacent sacrificial material; and
means for removing the sacrificial layer, wherein the housing of structural material with at least one aperture remains.

56. The apparatus of claim 55, wherein the means for applying a sacrificial material is at least configured to utilize sacrificial layer has a higher etch rate than the structural material.

57. The apparatus of claim 56, wherein the means for applying a sacrificial material is at least configured to utilize an organic material comprising with photoresist or polyimide.

58. The apparatus of claim 55, wherein the means for applying a structural material is at least configured to utilize a material selected from a group of Silicon Dioxide (SiO₂) and Silicon Nitride (Si₃N₄).

59. The apparatus of claim 55, wherein the means for removing portions of the structural layer is at least configured to use sputter etching or ion beam milling.

60. The apparatus of claim 55, wherein the means for removing the sacrificial layer is at least configured to use chemical etching.

61. The apparatus of claim 55, wherein the means for removing the sacrificial layer is at least configured to use plasma ashing or plasma etching.

62. The apparatus of claim 55, wherein the means for applying a structural material applies a structural layer between 0.2 microns and 20 microns thick.

63. The apparatus of claim 55, wherein the means for applying a sacrificial material applies a sacrificial layer is between 0.2 microns and 10 microns thick.

64. A method for packaging at least one microscopic device, comprising:
providing a gas atmosphere, wherein the pressure is greater than or equal to 1 Pascal (Pa);
providing a temperature of less than 600° Celsius (C);
forming a housing with at least one aperture over the at least one microscopic device;
depositing a protective material adjacent to the housing; and
curing the protective material.

65. An apparatus for packaging at least one microscopic device, comprising:
means for providing a gas atmosphere, wherein the pressure is greater than or equal to 1 Pascal (Pa);
means for providing a temperature of less than 600° Celsius (C);
means for forming a housing with at least one aperture over the at least one microscopic device;
means for depositing a protective material adjacent to the protective material; and
means for curing the protective material.

66. A method for packaging at least one microscopic device, comprising:
forming a housing with at least one aperture over the at least one microscopic device;
placing a protective material adjacent to at least a portion of the housing forming a protective layer on the housing, wherein the protective material extends at least partially into at least one aperture of the housing, sealing the aperture, but does not extend into at least one of the movable regions of the microscopic device; and
allowing or causing the protective layer to harden.

67. An apparatus for packaging a microscopic device, comprising:
a housing having at least a portion positioned out of contact with the microscopic device, and having one or more apertures; and
a protective layer deposited over the housing, wherein the protective layer comprises material at least partially extending into and sealing at least one aperture of the housing and remaining out of contact with the microscopic device.
